(19) United States
(12) Patent Application Publication
(10) Pub. No.: US 2025/0258248 A1
(43) Pub. Date: Aug. 14, 2025

(54) EQUIPMENT GROUND FAULT DETECTION CIRCUIT

(71) Applicant: SKYWORKS SOLUTIONS, INC., Irvine, CA (US)

(72) Inventor: Enrico Marcelo Sy, Mexicali (MX)

(21) Appl. No.: 19/044,720

(22) Filed: Feb. 4, 2025

Related U.S. Application Data
(60) Provisional application No. 63/553,176, filed on Feb. 14, 2024.

(51) Int. Cl. G01R 31/52; H02H 1/00; H02H 3/16

(52) U.S. Cl. CPC G01R 31/52; H02H 1/0007; H02H 3/16

(57) ABSTRACT

A system for monitoring a ground connection on electrical equipment is presented, the system including: a chassis ground; a virtual ground; a rectifier coupled to the chassis ground and configured to output a first voltage based on a virtual ground voltage and a chassis ground voltage; an instrumentation amplifier coupled to the rectifier to receive the first voltage and a second voltage, the instrumentation amplifier configured to output a third voltage based on the first voltage and a second voltage; and a controller coupled to the instrumentation amplifier. The controller is configured to receive the third voltage, determine whether the ground connection of the electrical equipment to the chassis ground is adequate based on the third voltage, and deactivate power to the electrical equipment responsive to determining that the ground connection is inadequate.

### CROSS-REFERENCE TO RELATED APPLICATIONS

This application claims priority under 35 U.S.C. § 119(e) to U.S. Provisional Patent Application 63/553,176 titled EQUIPMENT GROUND FAULT DETECTION CIRCUIT, filed on Feb. 14, 2024, and hereby incorporated by reference in its entirety for all purposes.

### BACKGROUND

### 1. Field of the Disclosure

At least one example in accordance with the present disclosure relates generally to continuously detecting faults in electrical systems.

### 2. Discussion of Related Art

Electrical equipment usually has a ground connection. Ground connections may be used to ground electrical currents, and can have safety applications.

### SUMMARY

According to at least one aspect of the present disclosure, a system for monitoring a ground connection on electrical equipment is presented, the system comprising: a chassis ground; a virtual ground; a rectifier coupled to the chassis ground and configured to output a first voltage based on a virtual ground voltage and a chassis ground voltage; an instrumentation amplifier coupled to the rectifier to receive the first voltage and a second voltage, the instrumentation amplifier configured to output a third voltage based on the first voltage and the second voltage; and a controller coupled to the instrumentation amplifier, the controller configured to receive the third voltage, determine whether the ground connection of the electrical equipment to the chassis ground is adequate based on the third voltage, and deactivate power to the electrical equipment responsive to determining that the ground connection is inadequate.

In some examples, the rectifier is a two stage amplifier having a first stage including a first-stage amplifier and a second stage including a second-stage amplifier. In some examples, the first stage comprises a first chassis ground connection configured to be coupled to the chassis ground, and a first virtual ground connection configured to be coupled to the virtual ground, wherein the first-stage amplifier is configured to provide a fourth voltage based on the virtual ground voltage and the chassis ground voltage. In some examples, the first stage further comprises a node; a first resistor coupled between the first chassis ground connection and the first-stage amplifier; a second resistor coupled to the node; a third resistor coupled to the second resistor and to a first diode, the first diode being coupled to an output of the first-stage amplifier; a second diode coupled to the second resistor and third resistor and further coupled to the output of the first-stage amplifier; and an inverting input of the rectifier coupled to the first diode and the first resistor. In some examples, the second stage comprises a second chassis ground connection configured to be coupled to the chassis ground; a second virtual ground connection configured to be coupled to the virtual ground; and a low voltage connection configured to be coupled to a low voltage, wherein the second-stage amplifier is configured to output the first voltage based on a node voltage of the node, the virtual ground voltage, and the chassis ground voltage. In some examples, the second stage further comprises a first resistor coupled between an output of the second-stage amplifier and the node; a second resistor coupled between the second chassis ground connection and an inverting input of the second-stage amplifier; and a third resistor coupled between the second virtual ground connection and a noninverting input of the second-stage amplifier, wherein the node is coupled to the inverting input of the second-stage amplifier. in some examples, the instrumentation amplifier is a three stage amplifier having a first stage including a first-stage amplifier, a second stage including a second-stage amplifier, and a third stage including a third-stage amplifier. In some examples, the first stage comprises a first connection configured to provide a first input voltage; a second connection configured to provide a second input voltage; a transient noise suppressor; a virtual ground connection coupled to the transient noise suppressor and configured to be coupled to the virtual ground; a first node configured to provide a fourth voltage based on an output voltage; and a first-stage amplifier, the first-stage amplifier configured to provide the output voltage based on the first input voltage. In some examples, the first input voltage is the first voltage. In some examples, the first stage further comprises a first resistor coupled between the first connection and the second connection; a second resistor coupled between the second connection and the transient noise suppressor; a third resistor coupled between the first node and an output of the first-stage amplifier; a fourth resistor coupled between the output of the first-stage amplifier and an inverting input of the first-stage amplifier; and a fifth resistor coupled between the first node and the virtual ground connection. In some examples, the second stage comprises the second connection; a second-stage amplifier configured to provide a second output voltage based on the second voltage; a second node configured to provide a fifth voltage based on the second output voltage; and a third node configured to provide a sixth voltage based on the second output voltage. In some examples, the second stage further comprises: a first resistor coupled between an output of the second-stage amplifier and an inverting input of the second-stage amplifier; a second resistor coupled between the output of the second-stage amplifier and the second node; and a third resistor coupled between the second node and the third node. In some examples, the third stage comprises: the first node; the second node; the third node; a fourth node; a controller connection configured to be coupled to the controller; and a third-stage amplifier configured to provide the third voltage based on fifth voltage and the sixth voltage. In some examples, the first node is coupled to a non-inverting input of the third-stage amplifier; the second node is coupled to an inverting input of the third-stage amplifier; the third node is coupled to an output of the third-stage amplifier; and the controller connection is coupled to the output of the third-stage amplifier. In some examples, the second voltage is based on the virtual ground voltage, the chassis ground voltage, and the first voltage.

According to at least one aspect of the present disclosure, a method for monitoring a ground connection of electrical equipment is presented, comprising: providing a first signal based on a chassis connection to a first amplifier; adjusting the first signal in the first amplifier; outputting a current from the first amplifier responsive to adjusting the first signal, the current being based on the first signal; splitting the current into a first current and a second current responsive to outputting the current; providing the first current to a second amplifier responsive to splitting the current; providing the second current to an impedance responsive to splitting the current; and providing a second signal at an output of the second amplifier responsive to providing the first current to the second amplifier, the second signal being based on the first current and the second current.

In some examples, the method further comprises, adjusting the second current by removing one or more transient elements of the second current and then providing the second current to a virtual ground responsive to providing the second current to the impedance. In some examples, adjusting the first signal includes: amplifying the first signal in a first stage of the first amplifier wherein a non-inverting input of the first stage is derived from a virtual ground; and amplifying the first signal in a second stage of the first amplifier responsive to amplifying the first signal in the first stage. In some examples, adjusting the second signal includes: amplifying the second signal in a third stage of the second amplifier wherein a non-inverting input of the third stage is derived from an output of the second stage; amplifying the second signal in a fourth stage responsive to amplifying the second signal in the third stage; and amplifying the second signal in a fifth stage responsive to amplifying in the second signal in the fourth stage. In some examples, amplifying the second signal in the fifth stage includes providing an output of the third stage to a non-inverting input of the fifth stage, and providing an output of the fourth stage to an inverting input of the fifth stage.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1A illustrates a fault detection system according to an example;

FIG. 1B illustrates a fault detection system according to an example;

FIG. 2 illustrates subsystem of a fault detection system according to an example;

FIG. 3 illustrates a two-stage operational amplifier rectifier according to an example;

FIG. 4 illustrates a three-stage instrumentation amplifier according to an example; and

FIG. 5 illustrates a combination of the first and second stages of the operational amplifier rectifier of FIG. 3 combined with the first, second and third stages of the instrumentation operational amplifier of FIG. 4.

### DETAILED DESCRIPTION

Electronic device processing equipment that is used to manufacture, test, package, etc. electronic devices that are sensitive to electrostatic discharges (ESD) often use robust ground connections to provide a degree of protection to the device and personnel. A robust ground connection will direct charge (often in the form of a current) from the equipment to Earth (or to another charge reservoir) where it can be safely absorbed.

In some examples, the processing equipment may have a dedicated ground connection, such as a wire or metal rod, that connects the equipment to ground. Oftentimes, the dedicated ground connection will attach to the chassis of the equipment, as an external connection can be easier to manage or access. However, because the equipment chassis acts as an intermediary element between the ground connection and the electrical circuit elements within the electronic device, it is possible for the electrical circuit elements to become separated from the ground connection. For example, the electrical circuit elements of the device may be connected to the chassis of the equipment by an internal wire or other connection that could come loose from the chassis or otherwise maintain a poor connection (e.g., a connection with a high level of resistance compared to other paths to ground, or an intermittent connection, and so forth).

Aspects and elements of the present disclosure relate to a system for improving the accuracy and consistency of the ground connection, reducing ground faults (such as single phase faults in small current grounding systems), and improving disconnection detection so that safeguards may be taken. In some examples, the ground connection is incorporated into the power connection (e.g., the power line connection), eliminating the need for an external ground connection.

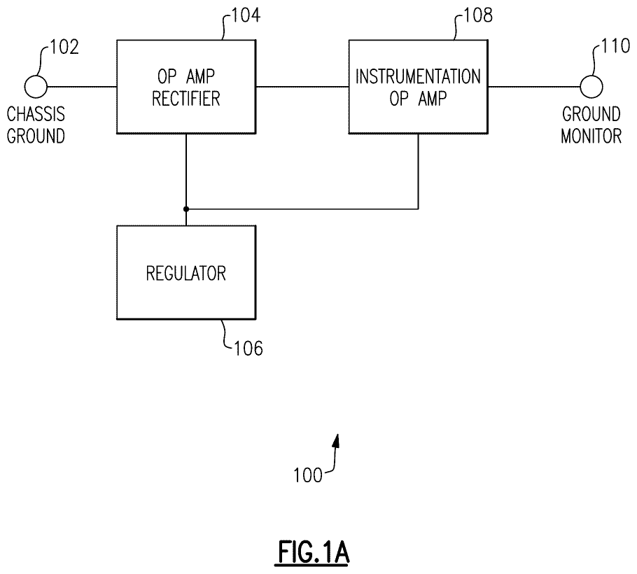

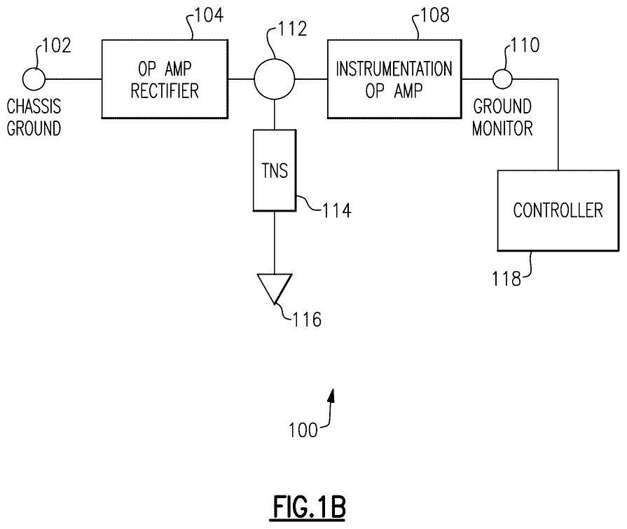

FIG. 1A illustrates a fault detection system 100 (“system 100”) according to an example. The system 100 includes a chassis connection 102, an operational amplifier (operational amplifier) rectifier 104, a regulator 106, an instrumentation operational amplifier, and a monitor connection 110.

The chassis connection 102 is coupled to the operational amplifier rectifier 104. The operational amplifier rectifier 104 is coupled to the chassis connection 102 at a first connection, the instrumentation operational amplifier 108 at a second connection, and the regulator 106 at a third connection. The regulator 106 is coupled to the operational amplifier rectifier 104 and instrumentation operational amplifier 108. The instrumentation operational amplifier 108 is coupled to the operational amplifier rectifier 104 at a first connection, the regulator 106 at a second connection, and the monitor connection 110 at a third connection.

The chassis connection 102 may be a connection to a ground of the equipment chassis or to another ground connection. The chassis connection 102 is used as an input to the operational amplifier rectifier 104. Thus, in some examples, voltage and/or current at the chassis connection 102 may be used as an input to the operational amplifier rectifier 104.

The operational amplifier rectifier 104 is an active rectifier that amplifies an input voltage and/or current and provides an output voltage and/or current to the instrumentation operational amplifier 108. In some examples, the operational amplifier rectifier 104 is a two stage amplifier, having at least a first stage amplifier and a second stage amplifier. In examples where the operational amplifier rectifier 104 is a two stage amplifier, the first stage may act as a buffer and rectifier with an expected voltage level equal to an input voltage modified by a scaling constant, G. Thus, the first stage of the amplifier may provide an output voltage, V₁, such that

$${V}_{1} = G \cdot {V}_{i n} \qquad ( 1 )$$

where Vᵢₙ is the input voltage. In some examples, the voltage V₁ may be provided only when Vᵢₙ is greater than zero. In some examples, G may be based on the impedances (e.g., resistance and/or reactance) of one or more impedances coupled to the first stage amplifier of the operational amplifier rectifier 104. The second stage of the operational amplifier rectifier 104 may amplify a differential voltage based on the output of the of the first stage amplifier and the input voltage and a scaling constant, K, such that:

$${V}_{r o a} = K \cdot ( {V}_{i n} + {V}_{1} ) \qquad ( 2 )$$

where Vᵣₒₐ is the output voltage of the operational amplifier rectifier 104 that is provided to the instrumentation operational amplifier 108. In some examples, K may be based on the impedances of one or more impedances coupled to the second stage amplifier of the operational amplifier rectifier 104.

The instrumentation operational amplifier 108 amplifies a differential voltage and/or current and rejects large common mode voltages and/or currents. In some examples, the instrumentation operational amplifier 108 may include three or more operational amplifiers and may have two or more stages. In examples where the instrumentation operational amplifier 108 has three stages, the instrumentation operational amplifier 108 may use two operational amplifiers (a first and a second operational amplifier) and various impedances to amplify the differential voltages and/or currents while keeping common mode voltage and/or current gain to a minimum (e.g., amplifying the common mode voltages and/or currents by an absolute value of 0 to 1). The instrumentation operational amplifier 108 may use a third operational amplifier and various impedances to amplify the difference mode voltage and/or current and reject the common mode voltage and/or current (e.g., not amplify the common mode voltage and/or current or amplify the common mode voltages and/or currents by an absolute value of 0 to 1). The instrumentation operational amplifier 108 may then provide the output of the third operational amplifier to the monitor connection 110.

In various examples, the reference (or ground) connections of the instrumentation operational amplifier 108 are coupled to a virtual ground.

The regulator 106 may provide power to the operational amplifier rectifier 104 and instrumentation operational amplifier 108. In some examples, the regulator 106 may provide power (e.g., VDD) to each operational amplifier of the operational amplifier rectifier 104 and instrumentation operational amplifier 108. In some examples, the regulator 106 may be a linear regulator, or a Low Dropout Regulator (LDO).

The monitor connection 110 is configured to receive the output of the instrumentation operational amplifier 108 and provide the voltage to a ground monitoring system, as will be discussed in greater detail herein.

In some examples, at least some and possibly all of the resistors and/or resistances within the operational amplifier rectifier 104 are equal. In some examples, at least some, and possibly all of the resistors and/or resistances within the instrumentation operational amplifier 108 are equal. The same may be true with respect to the reactances and/or impedances of one or both of the operational amplifier rectifier 104 and the instrumentation operational amplifier 108. However, the instrumentation operational amplifier 108 and operational amplifier rectifier 104 may have different resistances and/or impedances from one another.

FIG. 1B illustrates the system 100 according to an example. FIG. 1B expands upon the system 100 as it was presented in FIG. 1A by adding a current sensor 112, a transient noise suppressor 114, a virtual ground 116, and a controller 118. FIG. 1B omits the regulator 106 of FIG. 1A for clarity, however, the regulator 106 can be included. The monitor connection 110 is now additionally coupled to the controller 118.

While the operational amplifier rectifier 104 and the instrumentation operational amplifier 108 remain coupled together, a current sensor 112 now sits between them, configured to detect a current and/or voltage passing between the operational amplifier rectifier 104 and the instrumentation operational amplifier 108. The current sensor 112 is coupled to a transient noise suppressor 114. The transient noise suppressor 114 is coupled to the virtual ground 116.

The current sensor 112 senses a current and/or voltage between operational amplifier rectifier 104 and instrumentation operational amplifier 108. The current sensor 112 may be implemented in a number of ways. For example, the current sensor 112 may be implemented using a current transformer, or may be implemented using one or more resistors or other impedances. Thus, the current sensor 112 may be physically coupled to the connection between the operational amplifier rectifier 104 and the instrumentation operational amplifier 108, or may be electromagnetically coupled to said connection without a component in direct physical contact with said connection.

The transient noise suppressor 114 provides transient noise suppression to provide a more accurate reading of the current and/or voltage. Virtual ground 116 may act as a ground point with a lower voltage than the chassis connection 102 and/or the ground connection of the device chassis.

The controller 118 may be implemented as one or more processors, microcontrollers, application specific integrated circuits (ASICs), field programmable gate arrays (FPGAs), or other circuits. The controller 118 is configured to receive the output of the instrumentation operational amplifier 108 and interpret that output. In some examples, the controller 118 may determine the state of the ground connection (e.g., whether the ground connection is consistent, intermittent, missing, and so forth), may determine whether a fault has occurred, and may determine whether any anomalies are occurring or have occurred (and whether those anomalies are indicative of a fault or an undesirable state of the ground connection). The controller 118 may include machine learning software or other software that is configured to interpret the output of the instrumentation operational amplifier 108. The controller 118 may also be configured to provide an output signal to a switching device. The switching device may be configured to connect or disconnect the equipment or equipment chassis to power, and may be used to protect the equipment from fault conditions and to protect users from undesirable conditions that may apply to the equipment. In some examples, the controller 118 may be configured to control the switch to disconnect the equipment or equipment chassis from power for a predetermined amount of time (e.g., 1 ms, 5 ms, 1 second, 5 seconds, and so forth). The controller 118 may also issue an alert or alarm (e.g., via a siren, sending a message to an administrator, and/or using other methods) to indicate a fault condition or potential undesirable condition without manual interference. In some examples, the controller 118 may ensure that the electrical equipment is never disconnected from the earth ground.

Furthermore, most fault detection systems and ground connections are checked for issues during maintenance, but are not typically monitored between maintenance intervals. The fault detection system 100 of the present disclosure allows for continuous monitoring of the equipment and ground connections in real-time.

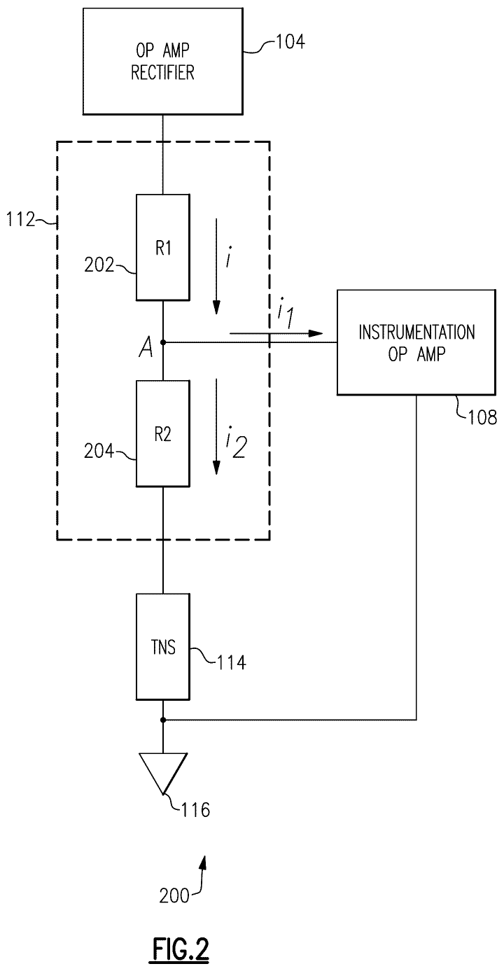

FIG. 2 illustrates a subsystem 200 of the system 100 of FIGS. 1A and 1B according to an example. The subsystem 200 adds a first sense impedance 202 (“first impedance 202”) and a second sense impedance 204 (“second impedance 204”) to the system 100 as part of the current sensor 112. The first impedance 202 may have a lower resistance and/or impedance compared to the second impedance 204. For example, the first impedance 202 may have a resistance less than 1 Ohm and the second impedance 204 may have a resistance greater than 1 Ohm. In some examples, the first impedance 202 may have a resistance of 0.4 Ohms, and the second impedance 204 may have a resistance of 5 Ohms. In some examples, the first impedance 202 may have approximately 1/10^{th} the resistance of the second impedance 204. The first impedance 202 and the second impedance 204 act or may act as a voltage divider.

The operational amplifier rectifier 104 is coupled to the first impedance 202. The first impedance 202 is coupled at a first terminal to the operational amplifier rectifier 104 and at a second terminal to the second impedance 204 and instrumentation operational amplifier 108 (e.g., at node A). The second impedance 204 is coupled at a first terminal to the first impedance 202 and to the instrumentation operational amplifier 108 (e.g., at node A), and at a second terminal to the transient noise suppressor 114. The transient noise suppressor 114 is coupled to the instrumentation operational amplifier 108 at a first connection and to the second impedance 204 at a second connection. The connection that the transient noise suppressor 114 and instrumentation operational amplifier 108 share is also coupled to the virtual ground 116.

The operational amplifier rectifier 104 may provide a current, i, to the current sensor 112. The current, i, may be provided to the first impedance 202 and may enter node A. In node A, the current may split, with a first portion, i₁, going to the instrumentation operational amplifier 108, and a second portion, i₂, going to the second impedance 204 and to the transient noise suppressor 114. Alternatively, the current i and i₂ may be combined at node A to produce i₁.

The transient noise suppressor 114 may attenuate transients (e.g., transient voltages and/or currents) that may be present in and/or related to the currents i, i₁, and/or i₂.

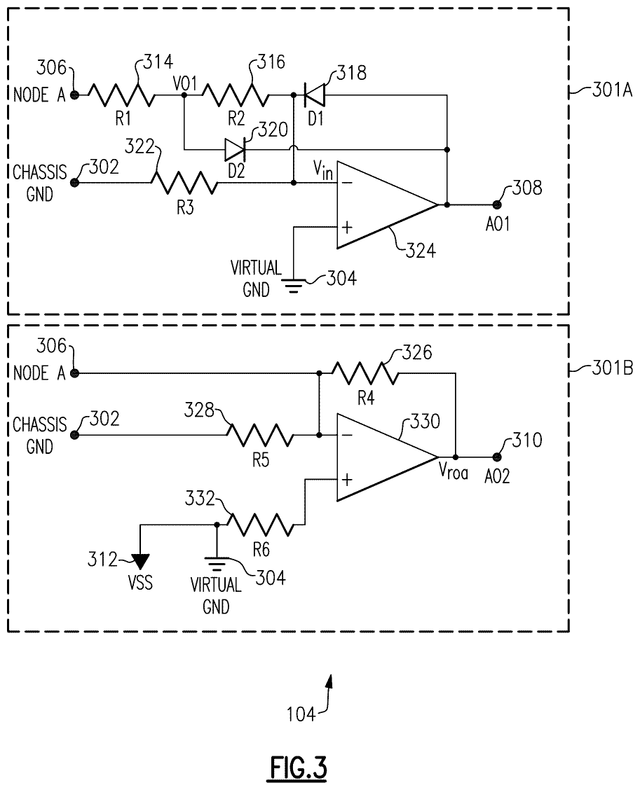

FIG. 3 illustrates the two-stage operational amplifier rectifier 104 according to an example. The operational amplifier rectifier 104 may include a first stage 301A and a second stage 301B. The operational amplifier rectifier 104 may include, in some examples, a chassis ground connection 302, a virtual ground connection 304, a first node 306 (“node A”), a first output 308, a second output 310, a low voltage connection 312, a first resistor 314, a second resistor 316, a first diode 318, a second diode 320, a third resistor 322, a first amplifier 324, a fourth resistor 326, a fifth resistor 328, a second amplifier 330, and/or a sixth resistor 332. Any of the resistors 324, 326, 322, 326, 328, and/or 332 may be impedances (e.g., have both resistance and reactance).

The operational amplifier rectifier 104 may act as a full-wave rectifier, with the first stage 301A acting as a half-wave rectifier, and the second stage 301B acting to complete the full-wave rectification (e.g., rectifying the portions of the current and/or voltage not rectified during the first stage 301A). The second stage 301B may subtract Vᵢₙ from the output signal, where Vᵢₙ may be at least an input voltage and/or current to the first stage 301A of the operational amplifier rectifier 104.

The chassis ground connection 302 is coupled to the third resistor 322 and to the fifth resistor 328. The virtual ground connection 304 is coupled to the low voltage connection 312, the sixth resistor 332, and to an input of the first amplifier 324. In some examples, the virtual ground connection 304 is coupled to the positive input (e.g. the non-inverting input) of the first amplifier 324. The first node 306 is coupled to the first resistor 314, the fourth resistor 326, and the fifth resistor 328.

The first output 308 is coupled to an output of the first amplifier 324, to the first diode 318, and to the second diode 320. In some examples, the first output 308 is coupled to the anode of the first diode 318 and to the cathode of the second diode 320.

The second output 310 is coupled to an output of the second amplifier 330 and to the fourth resistor 326. In some examples, the second output 310 is the output of the operational amplifier rectifier 104 and provides a voltage and/or current to the instrumentation operational amplifier 108, current sensor 112, and/or transient noise suppressor 114.

The low voltage connection 312 is coupled to the virtual ground connection 304 and to the sixth resistor 332.

The first resistor 314 is coupled, at a first terminal, to the first node 306, and at a second terminal to the second resistor 316 and to the second diode 320. In some examples, the first resistor 314 is coupled to an anode of the second diode 320. The second resistor 316 is coupled at a first terminal to the first resistor 314 and to the second diode 320, and at a second terminal to the first diode 318, the third resistor 322, and an input of the first amplifier 324. In some examples, the second resistor 316 is coupled to a cathode of the first diode 318, an anode of the second diode 320, and a negative (e.g., inverting) input of the first amplifier 324.

The first diode 318 is coupled at a first terminal to the second resistor 316 and the third resistor 322, at a second terminal to the first output 308, and at one or more terminals to the first amplifier 324. In some examples, an anode of the first diode 318 is coupled to the first output 308 and to an output of the first amplifier 324, and a cathode of the first diode 318 is coupled to the second resistor 316, the third resistor 322, and to a negative (e.g., inverting) input of the first amplifier 324.

The second diode 320 is coupled at a first terminal to the first resistor 314 and the second resistor 316, and at a second terminal to the first amplifier 324 and the first output 308. In some examples, an anode of the second diode 320 is coupled to the first resistor 314 and the second resistor 316, and a cathode of the second diode 320 is coupled to the first output 308 and to an output of the first amplifier 324.

The third resistor 322 is coupled at a first terminal to the chassis ground connection 302, and at a second terminal to the second resistor 316, first diode 318, and first amplifier 324. In some examples, the third resistor 322 is coupled to a cathode of the first diode 318 and to a negative (e.g., inverting) input of the first amplifier 324. The fourth resistor 326 is coupled at a first terminal to the second output 310, at a second terminal to the first node 306 and the fifth resistor 328, and at one or more terminals to the second amplifier 330. In some examples, the fourth resistor 326 is coupled to an output of the second amplifier 330 and to a negative (e.g., inverting) input of the second amplifier 330. The fifth resistor 328 is coupled at a first terminal to the chassis ground connection 302, and at a second terminal to the first node 306, the fourth resistor 326, and the second amplifier 330. In some examples, the fifth resistor 328 is coupled to a negative (e.g., inverting) input of the second amplifier 330. The sixth resistor is coupled at a first terminal to the virtual ground connection 304 and to the low voltage connection 312, and at a second terminal to the second amplifier 330. In some examples, the sixth resistor is coupled to a positive (e.g., non-inverting) input of the second amplifier 330.

The selection of diodes and/or resistors for the operational amplifier rectifier 104 may be determined based on the frequency range and/or bandwidth of noises associated with the electrical equipment, which may be variable or constant.

The first stage 301A, as mentioned above, may operate as a half-wave rectifier. The output voltage of the first amplifier may be expressed as:

$$V O 1 = {V}_{i n} \cdot \frac{R 3}{R 2} \qquad ( 3 )$$

where VO1 is the voltage at node VO1 (the node linking the first resistor 314, the second resistor 316, and the second diode 320), R2 is the resistance of the second resistor 316, R3 is the resistance of the third resistor 322, and Vᵢₙ is an input voltage (e.g., a voltage at the negative or inverting input of the first amplifier 324). In some examples, the first amplifier 324 may only provide an output when Vᵢₙ is greater than and/or equal to zero.

The second stage 301B operates to complete the rectification of the input and to capture the voltage difference between the chassis ground and the virtual ground. In particular, the second stage 301B amplifies the difference between the chassis ground and virtual ground before providing that difference (in the form of the output of the second amplifier 330) to the instrumentation operational amplifier 108.

The output of the second amplifier 330 is based on the inputs provided to its first and second input, and may represent a sum of Vᵢₙ and VO1 modified by the scaling factor, K. K may be greater than zero. Thus, the output of the second stage, Vᵣₒₐ may be expressed as:

$${V}_{r o a} = K \cdot ( {V}_{in} + V O 1 ) \qquad ( 4 )$$

The first input may be the negative (or inverting) input, and the second input may be the positive (or non-inverting) input. The voltage at the inverting input is based upon the voltage at node VO1, the chassis ground connection 302, and the second output 310, each of which are connected to the first node 306 via a resistor (e.g., the first resistor 314, the fourth resistor 326, and the fifth resistor 328). The voltage at the non-inverting input is based upon the voltage at the virtual ground 304 and/or the low voltage connection 312 because those are connected to the non-inverting input via the sixth resistor 332. The low voltage connection 312 may be tied to the lowest voltage provided to the system, rather than to a reference voltage. Thus, the low voltage connection 312 may be coupled to a positive voltage, the ground (zero voltage), and/or a negative voltage.

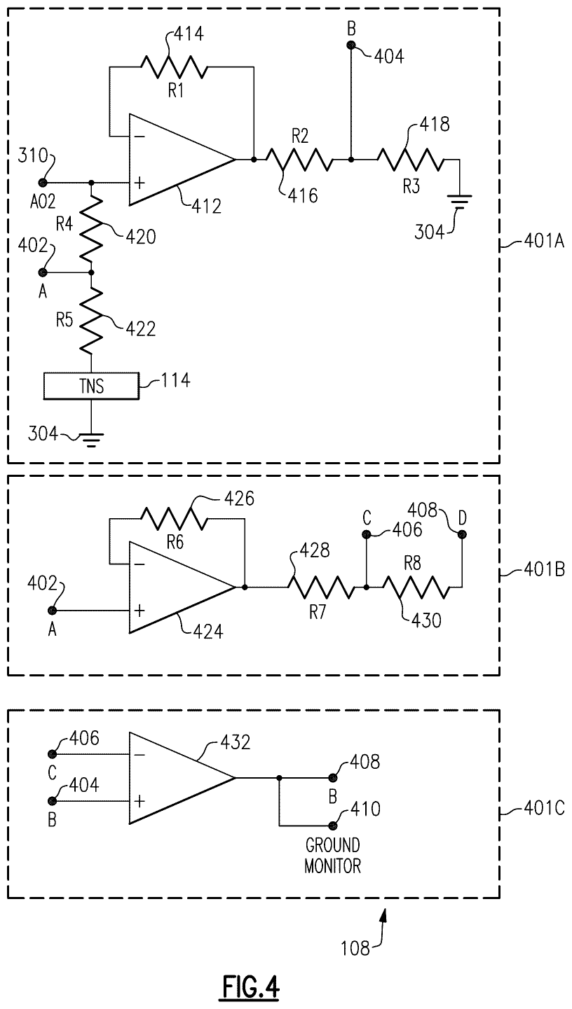

FIG. 4 illustrates the instrumentation operational amplifier 108 according to an example. The instrumentation operational amplifier 108 may have three stages, including a first stage 401A, a second stage 401B, and a third stage 401C.

The instrumentation operational amplifier 108 may be coupled to the virtual ground (e.g., virtual ground connection 304 of FIG. 3). That is, the instrumentation operational amplifier 108 may use the virtual ground connection 304 to provide a reference voltage rather than using the chassis ground. As a result, the instrumentation operational amplifier 108 may be able to differentiate the effect of the virtual ground compared to that of the chassis ground, which allows the instrumentation operational amplifier 108 to detect and/or determine the voltage difference between the potential at the chassis ground and the potential at the virtual ground. The instrumentation operational amplifier 108 may generate an output signal based on the differential between the chassis ground and virtual ground and/or based on a signal corresponding to the potential of the chassis ground and a signal corresponding to the potential of the virtual ground.

The instrumentation operational amplifier 108 may provide an output to the ground monitor 110 and may be used by the controller 118 to determine if variances between the chassis ground and virtual ground exist and require the electrical equipment to be deactivated and/or stopped until the variances stop.

The instrumentation operational amplifier 108 includes the second output 310, the virtual ground connection 304, a first node 402 (“node A”), a second node 404 (“node B”), a third node 406 (“node C”), a fourth node 408 (“node D”), a ground monitor connection 410, a first amplifier 412, a first resistor 414, a second resistor 416, a third resistor 418, a fourth resistor 420, a fifth resistor 422, a second amplifier 424, a sixth resistor 426, a seventh resistor 428, an eighth resistor 430, and a third amplifier 432.

The first amplifier 412 is coupled to the second output 310, the first resistor 414, the second resistor 416, and the fourth resistor 420. In some examples, the non-inverting input of the first amplifier 412 is coupled to the second output 310 and to the fourth resistor 420, the inverting input is coupled to the first resistor 414, and the output is coupled to the first resistor 414 and the second resistor 416. The second resistor 416 is coupled at a first terminal to the first resistor 414 and the amplifier 412, and at a second terminal to the second node 404 and the third resistor 418. The third resistor 418 is coupled at a first terminal to the second resistor 416 and the second node 404, and at a second terminal to the virtual ground connection 304. The fourth resistor 420 is coupled at a first terminal to the first amplifier 412 and the second output 310, and at a second terminal to the first node 402 and the fifth resistor 422. The fifth resistor is further coupled to the transient noise suppressor 114, and the transient noise suppressor 114 is coupled to the virtual ground connection 304.

The second amplifier 424 is coupled to the first node 402, the sixth resistor 426, and the seventh resistor 428. In some examples, the non-inverting input of the second amplifier 424 is coupled to the first node 402, the inverting input is coupled to the sixth resistor 426, and the output is coupled to the sixth resistor 426 and the seventh resistor 428. The sixth resistor 426 is coupled at a first terminal to the amplifier 424, and at a second terminal to the amplifier 424 and the seventh resistor 428. The seventh resistor 428 is coupled at a first terminal to the amplifier 424 and the sixth resistor 426, and at a second terminal to the third node 406 and the eighth resistor 430. The eighth resistor 430 is coupled at a first terminal to the seventh resistor 428 and the third node 406, and at a second terminal to the fourth node 408.

The third amplifier 432 is coupled to the second node 404, the third node 406, the fourth node 408, and the ground monitor 410. In some examples, the non-inverting input of the third amplifier 432 is coupled to the second node 404, the inverting input is coupled to the third node 406, and the output is coupled to the fourth node 408 and the ground monitor 410.

The output of the second output 310 is provided to the non-inverting input of the first amplifier 412. A voltage and/or current based on the output at the second output 310 is also provided to the non-inverting input of the second amplifier 424. The output of the first stage 401A is provided at the second node 404 to the non-inverting input of the third amplifier 432. The output of the second stage 401B is provided to the third node 406 and the fourth node 408. Because the third node 406 and fourth node 408 are separated via at least the eighth resistor 430, the current and/or voltage at the third node 406 may differ from that at the fourth node 408. The current and/or voltage at the third node 406 is provided to the inverting input of the third amplifier 432. The current and/or voltage at the fourth node 408 is provided to the ground monitor 410. The third amplifier 432 provides an output current and/or voltage to the fourth node 408 and ground monitor 410. Whether the third amplifier 432 provides an output may depend on the difference in voltage between the second node 404 and third node 406. Likewise, the output of the third amplifier 432 may depend on the voltages and/or currents at the second node 404 and third node 406.

As a result, the final output of the third amplifier 432 may be a signal that represents a difference between the voltage at the chassis ground and the voltage at the virtual ground 304. Should the signal generated by the third amplifier 432 fall outside a given range and/or exceed a given threshold, the ground monitor 110 (receiving said signal from the ground monitor connection 410) may disable the electrical equipment temporarily or permanently (e.g., until the signal returns to the given range and/or falls below the threshold).

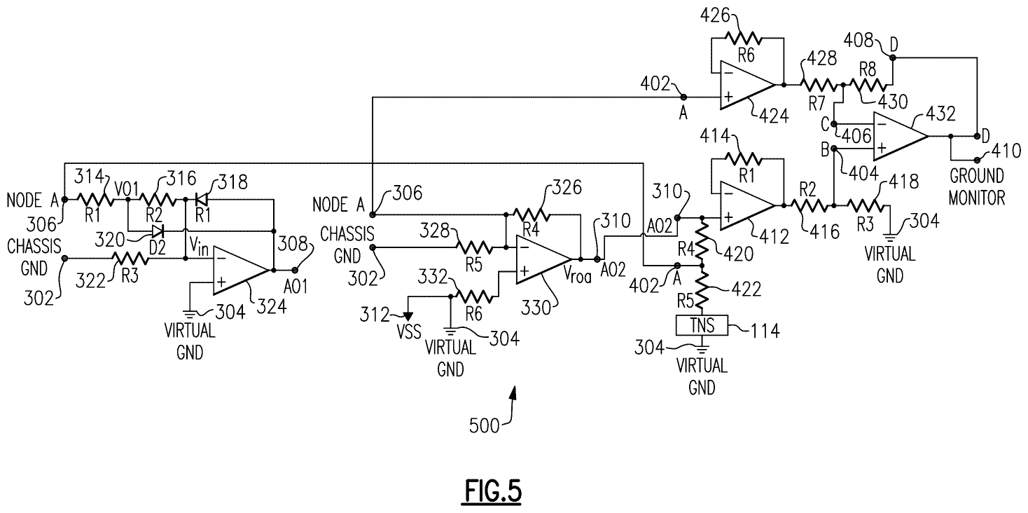

FIG. 5 illustrates a combination of the first stage 301a and second stage 301b of the operational amplifier rectifier 104 combined with the first stage 401a, second stage 401b, and third stage 401c of the instrumentation operational amplifier 108. FIG. 5 is equivalent to FIGS. 3 and 4, except that it explicitly shows connections between the stages 301a, 301b, 401a, 401b, 401c rather than using node labels to illustrate said connections.

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers, such as the controller 118, may execute various operations discussed above. Using data stored in associated memory and/or storage, the controller 118 also executes one or more instructions stored on one or more non-transitory computer-readable media, which the controller 118 may include and/or be coupled to, that may result in manipulated data. In some examples, the controller 118 may include one or more processors or other types of controllers. In one example, the controller 118 is or includes at least one processor. In another example, the controller 118 performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A system for monitoring a ground connection on electrical equipment, the system comprising:
a chassis ground;
a virtual ground;
a rectifier coupled to the chassis ground and configured to output a first voltage based on a virtual ground voltage and a chassis ground voltage;
an instrumentation amplifier coupled to the rectifier to receive the first voltage and a second voltage, the instrumentation amplifier configured to output a third voltage based on the first voltage and the second voltage; and
a controller coupled to the instrumentation amplifier, the controller configured to
receive the third voltage,
determine whether the ground connection of the electrical equipment to the chassis ground is adequate based on the third voltage, and
deactivate power to the electrical equipment responsive to determining that the ground connection is inadequate.

2. The system of claim 1 wherein the rectifier is a two stage amplifier having a first stage including a first-stage amplifier and a second stage including a second-stage amplifier.

3. The system of claim 2 wherein the first stage comprises
a first chassis ground connection configured to be coupled to the chassis ground, and
a first virtual ground connection configured to be coupled to the virtual ground, wherein the first-stage amplifier is configured to provide a fourth voltage based on the virtual ground voltage and the chassis ground voltage.

4. The system of claim 3 wherein the first stage further comprises
a node;
a first resistor coupled between the first chassis ground connection and the first-stage amplifier;
a second resistor coupled to the node;
a third resistor coupled to the second resistor and to a first diode, the first diode being coupled to an output of the first-stage amplifier;
a second diode coupled to the second resistor and third resistor and further coupled to the output of the first-stage amplifier; and
an inverting input of the rectifier coupled to the first diode and the first resistor.

5. The system of claim 3 wherein the second stage comprises
a second chassis ground connection configured to be coupled to the chassis ground;
a second virtual ground connection configured to be coupled to the virtual ground; and
a low voltage connection configured to be coupled to a low voltage,
wherein the second-stage amplifier is configured to output the first voltage based on a node voltage of the node, the virtual ground voltage, and the chassis ground voltage.

6. The system of claim 5 wherein the second stage further comprises
a first resistor coupled between an output of the second-stage amplifier and the node;
a second resistor coupled between the second chassis ground connection and an inverting input of the second-stage amplifier; and
a third resistor coupled between the second virtual ground connection and a noninverting input of the second-stage amplifier, wherein the node is coupled to the inverting input of the second-stage amplifier.

7. The system of claim 1 wherein the instrumentation amplifier is a three stage amplifier having a first stage including a first-stage amplifier, a second stage including a second-stage amplifier, and a third stage including a third-stage amplifier.

8. The system of claim 7 wherein the first stage comprises
a first connection configured to provide a first input voltage;
a second connection configured to provide a second input voltage;
a transient noise suppressor;
a virtual ground connection coupled to the transient noise suppressor and configured to be coupled to the virtual ground;
a first node configured to provide a fourth voltage based on an output voltage; and
a first-stage amplifier, the first-stage amplifier configured to provide the output voltage based on the first input voltage.

9. The system of claim 8 wherein the first input voltage is the first voltage.

10. The system of claim 8 wherein the first stage further comprises
a first resistor coupled between the first connection and the second connection;
a second resistor coupled between the second connection and the transient noise suppressor;
a third resistor coupled between the first node and an output of the first-stage amplifier;
a fourth resistor coupled between the output of the first-stage amplifier and an inverting input of the first-stage amplifier; and
a fifth resistor coupled between the first node and the virtual ground connection.

11. The system of claim 8 wherein the second stage comprises
the second connection;
a second-stage amplifier configured to provide a second output voltage based on the second voltage;
a second node configured to provide a fifth voltage based on the second output voltage; and
a third node configured to provide a sixth voltage based on the second output voltage.

12. The system of claim 11 wherein the second stage further comprises:
a first resistor coupled between an output of the second-stage amplifier and an inverting input of the second-stage amplifier;
a second resistor coupled between the output of the second-stage amplifier and the second node; and
a third resistor coupled between the second node and the third node.

13. The system of claim 11 wherein the third stage comprises:
the first node;
the second node;
the third node;
a fourth node;
a controller connection configured to be coupled to the controller; and
a third-stage amplifier configured to provide the third voltage based on fifth voltage and the sixth voltage.

14. The system of claim 13 wherein:
the first node is coupled to a non-inverting input of the third-stage amplifier;
the second node is coupled to an inverting input of the third-stage amplifier;
the third node is coupled to an output of the third-stage amplifier; and
the controller connection is coupled to the output of the third-stage amplifier.

15. The system of claim 1 wherein the second voltage is based on the virtual ground voltage, the chassis ground voltage, and the first voltage.

16. A method for monitoring a ground connection of electrical equipment, comprising:
providing a first signal based on a chassis connection to a first amplifier;
adjusting the first signal in the first amplifier;
outputting a current from the first amplifier, the current being based on the first signal;
splitting the current into a first current and a second current;
providing the first current to a second amplifier;
providing the second current to an impedance; and
providing a second signal at an output of the second amplifier, the second signal being based on the first current and the second current.

17. The method of claim 16 further comprising, adjusting the second current by removing one or more transient elements of the second current and then providing the second current to a virtual ground.

18. The method of claim 16 wherein adjusting the first signal includes:
amplifying the first signal in a first stage of the first amplifier wherein a non-inverting input of the first stage is derived from a virtual ground; and
amplifying the first signal in a second stage of the first amplifier.

19. The method of claim 18 wherein adjusting the second signal includes:
amplifying the second signal in a third stage of the second amplifier wherein a non-inverting input of the third stage is derived from an output of the second stage;
amplifying the second signal in a fourth stage; and
amplifying the second signal in a fifth stage.

20. The method of claim 19 wherein amplifying the second signal in the fifth stage includes providing an output of the third stage to a non-inverting input of the fifth stage, and providing an output of the fourth stage to an inverting input of the fifth stage.
